(19) United States
(12) Patent Application Publication
(10) Pub. No.: US 2024/0355752 A1
(43) Pub. Date: Oct. 24, 2024

(54) GLASS PACKAGE SUBSTRATE WITH CHIP DISAGGREGATION INTERFACE

(71) Applicant: Intel Corporation, Santa Clara, CA (US)

(72) Inventor: Telesphor KAMGAING, Chandler, AZ (US)

(21) Appl. No.: 18/138,440

(22) Filed: Apr. 24, 2023

(51) Int. Cl. H01L 23/538; H01L 21/48; H01L 23/15

(52) U.S. Cl. CPC H01L 23/5386; H01L 21/486; H01L 23/15; H01L 23/5384; H01L 24/16; H01L 24/32; H01L 24/73; H01L 24/81; H01L 24/83; H01L 24/92; H01L 25/0655; H01L 25/16; H01L 2224/16227; H01L 2224/32225; H01L 2224/73204; H01L 2224/81801; H01L 2224/83102; H01L 2224/92125

(57) ABSTRACT

Embodiments disclosed herein include a package substrate. In an embodiment, the package substrate comprises a core with a first surface and a second surface, where the core comprises a glass layer. In an embodiment, a first routing layer is over the first surface of the core, where the first routing layer comprises traces with a first width. In an embodiment, a second routing layer is over the second surface of the core, where the second routing layer comprises traces with a second width that is smaller than the first width.

### TECHNICAL FIELD

Embodiments of the present disclosure relate to electronic systems, and more particularly, to electronic packages with a glass substrate with traces with high density line width/spacing (L/S) on one side and traditional buildup layers on the other side.

### BACKGROUND

In order to provide high yielding dies, advanced computing systems utilize a packaging architecture referred to as die disaggregation. In die disaggregation, individual chiplets with a smaller footprint are stitched together with an underlying base die, interposer, and/or the like. The smaller footprint of the chiplets allows for advanced processing nodes to be enabled with a higher yield compared to an architecture where all of the computing power was provided on a single, larger, die. However, die disaggregation approaches have led to more complex packaging architectures. Generally, high density routing is needed to communicatively couple the chiplets together.

The high density routing can be implemented through various packaging solutions. In one instance, a bridge die is embedded within a standard organic package substrate. The bridge die may be a silicon or glass die that enables the high density routing. In other embodiments, a base die is provided below the chiplets. The base die may be at a less advanced processing node than the chiplets.

In many advanced packaging architecture glass layers are used to enable stiffer structures. This allows for larger form factors. When glass is used as a core in a multi-layer package substrate, it is still necessary to use a structure such as one with a base die below the chiplets. This increases assembly complexity and costs. Using the glass as a traditional interposer adds to the system height, increases costs, and can lead to potential reliability issues.

### BRIEF DESCRIPTION OF THE DRAWINGS

FIG. 1 is a cross-sectional illustration of an electronic package with a base die and a glass interposer.

FIG. 2A is a cross-sectional illustration of an electronic package with a glass core with high density redistribution layers on one side and traditional buildup layers on the opposite side, in accordance with an embodiment.

FIG. 2B is a plan view illustration of a redistribution layer with high density routing in an electronic package, in accordance with an embodiment.

FIG. 2C is a plan view illustration of a buildup layer with less dense routing in the buildup layer of an electronic package, in accordance with an embodiment.

FIG. 3 is a cross-sectional illustration of an electronic package with a glass core with a buffer layer between the glass core and the redistribution layers, in accordance with an embodiment.

FIG. 4 is a cross-sectional illustration of an electronic package with a glass core that includes vias with an hourglass shaped cross-section, in accordance with an embodiment.

FIGS. 5A-5K are cross-sectional illustrations depicting a process for fabricating an electronic package, in accordance with an embodiment.

FIG. 6 is a cross-sectional illustration of an electronic system with a package substrate that comprises a glass core, in accordance with an embodiment.

FIG. 7 is a schematic of a computing device built in accordance with an embodiment.

### EMBODIMENTS OF THE PRESENT DISCLOSURE

Described herein are electronic systems, and more particularly, electronic packages with a glass substrate with traces with high density line width/spacing (L/S) on one side and traditional buildup layers on the other side, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

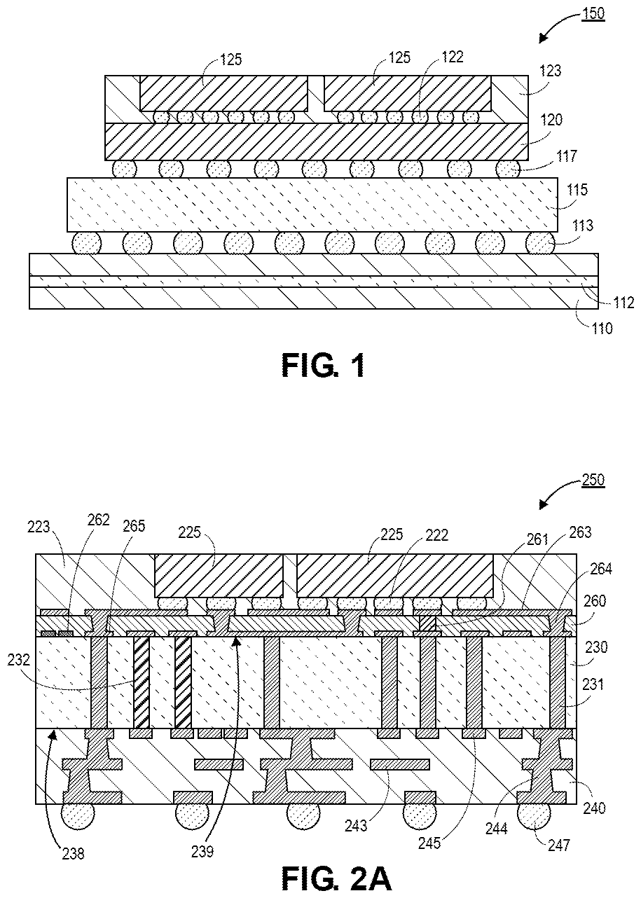

As noted above, electronic packaging is moving towards the use of more die disaggregation approaches. One such die disaggregation approach is the electronic package 150 shown in FIG. 1. As shown, a package substrate 110 may be provided as a base. The package substrate 110 may be a multi-layer structure. For example, organic buildup film layers may be laminated over each other. The package substrate 110 may also include a core 112, such as a glass core 112.

An interposer 115 may be provided over the package substrate 110. For example, interconnects 113 may couple the interposer 115 to the package substrate 110. The interposer 115 may also be a glass layer with interconnects in some instances. The use of a glass interposer 115 provides improved stiffness to the electronic package 150. However, the glass interposer 115 also increases complexity, costs, and Z-height form factor.

A multi-die module may be coupled to the interposer 115. The multi-die module may include a base die 120. The base die 120 communicatively couples together two or more chiplets or dies 125. The dies 125 may be coupled to the base die 120 through interconnects 122, and the base die 120 may be coupled to the interposer 115 through interconnects 117. The dies 125 may be embedded in a mold layer 123, or may otherwise be underfilled.

As illustrated, the electronic package 150 has a significant Z-height penalty due to all of the layers between the dies 125 and the package substrate 110. In addition to large Z-heights, the complexity of the electronic package 150 is high, which drives up costs. Accordingly, such an electronic package 150 may not be suitable for applications where form factor is restricted. For example, mobile devices may not be able to accommodate such large Z-heights. Additionally, the multiple different interconnect layers lead to reliability concerns.

Accordingly, embodiments disclosed herein include electronic packages that omit the interposer and the base die. This is done through the use of a package substrate that includes a high density routing layer, or redistribution layer, provided over a glass core. The glass core provides a dimensionally stable structure on which traces with fine line width/spacing (L/S) dimensions can be fabricated. For example, embodiments disclosed herein may allow for L/S dimensions that are approximately 5 μm/5 μm or less, or approximately 1 μm/1 μm or less. As used herein, “approximately” may refer to a range of values that are within fifty percent of the stated value. For example, approximately 1 μm may refer to a range between 0.5 μm and 1.5 μm.

In addition to providing a substrate that enables high density traces, the glass core may enable integration of one or more different passive structures into the electronic package. As used herein, “integration” of passives may refer to a process where the passive devices are fabricated along with the process flow of the electronic package fabrication. That is, integrated passives are different than discrete devices that are embedded in the electronic package. Embodiments disclosed herein allow for integration of passives, such as, but not limited to, resistors, capacitors, and inductors.

In addition to a reduction in the Z-height provided by embodiments disclosed herein, embodiment enable more robust electronic packages. Removing the multiple interconnect layers removes possible locations for damage. More particularly, embodiments may include only a single layer of interconnects between the dies and the bottom of the package substrate.

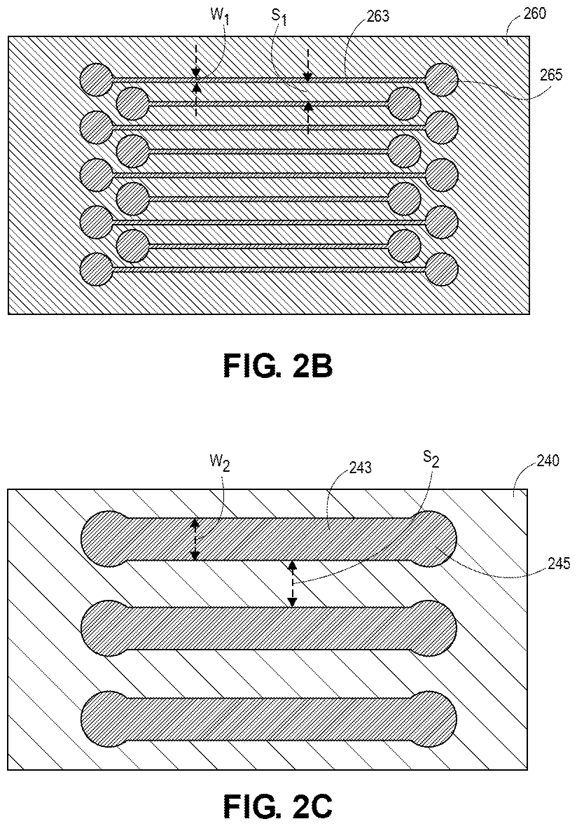

Referring now to FIG. 2A, a cross-sectional illustration of an electronic package 250 is shown, in accordance with an embodiment. In an embodiment, the electronic package 250 includes a core 230. The core 230 may comprise glass. More particularly, the core 230 may include a glass layer. The glass of the core 230 may be a glass formulation that is compatible with laser assisted etching processes. For example, the glass may comprise silicon, boron and silicon, or silicon with other dopants. The glass may be a fused silicon (e.g., an amorphous silicon) material. In an embodiment, the glass may comprise 70% or more silicon, 90% or more silicon, or 99% or more silicon. In an embodiment, the core 230 may have a thickness that is up to approximately 1,000 μm thick. In a particular embodiment, the core 230 may have a thickness between 50 μm and 500 μm. Though, it is to be appreciated that thicker or thinner cores 230 may also be used in some embodiments. Glass layers or layers comprising glass may refer to layers that are substantially all glass. This is in contrast to some packaging materials, such as prepreg, that include dielectric layers that are reinforced by glass fibers.

In an embodiment, vias 231 may be provided through a thickness of the core 230. The vias 231 may comprise copper or other conductive material (or materials). For example, the vias 231 may include seed layers, adhesion layers, or the like. The vias 231 may be formed with a laser assisted etching process followed by a suitable plating process. In the illustrated embodiments, the vias 231 are fully filled. In other embodiments, the vias 231 may include a conductive shell that lines the via opening with an insulating plug within the conductive shell. In an embodiment, diameters of the vias 231 may be approximately 100 μm or less, approximately 50 μm or less, or approximately 20 μm or less. Though, larger diameters may also be used for the vias 231.

In an embodiment, one or more inductors 232 may be integrated into the core 230. The inductors 232 may be coaxial inductor structures. Generally, the inductors 232 may comprise a magnetic material shell with a conductive via within the magnetic shell. The magnetic material may be a magnetic paste, a plated magnetic material, or the like. For example, the magnetic material may be a ferrite based material in some embodiments.

In an embodiment, first routing layers 240 may be provided over a first surface 238 of the core 230. The first routing layers 240 may comprise conventional buildup materials, such as organic buildup film. Conductive routing (e.g., pads 245, traces 243, and vias 244) may be provided through the first routing layers 240. The traces 243 in the first routing layers 240 may have L/S dimensions that are approximately 5 μm/5 μm or larger, or approximately 10 μm/10 μm or larger. In an embodiment, interconnects 247 may be provided at a bottom of the first routing layers 240. The interconnects 247 are shown as solder bumps, but it is to be appreciated that any second level interconnect (SLI) architecture may be used.

In an embodiment, second routing layers 260 may be provided over a second surface 239 of the core 230. The second routing layers 260 may sometimes be referred to as redistribution layers. In an embodiment, the second routing layers 260 may comprise any material suitable for patterning high density routing. For example, the second routing layers 260 may comprise silicon and oxygen (e.g., SiO₂), silicon and nitrogen (e.g., SiN_{X}), or a polymer (e.g., benzocyclobutene (BCB)). In the illustrated embodiment, the second routing layers 260 may include any number of layers. For example, two second routing layers 260 are shown in FIG. 2A. In some embodiments, four or more second routing layers 260 may be used.

The second routing layers 260 may comprise conductive routing (e.g., pads 265, traces 263, and vias 264). In an embodiment the traces 263 may have L/S dimensions that are smaller than those of the traces 243 in the first routing layers 240. For example, L/S dimensions of the traces 263 may be approximately 5 μm/5 μm or less, or approximately 1 μm/1 μm or less.

In an embodiment, passives may be integrated into the second routing layers 260. For example, capacitors 261 and resistors 262 may be fabricated along with the conductive routing of the second routing layers 260. Resistors 262 may be fabricated as a trace (e.g., a serpentine trace) that is formed in one of the routing layers 260. Resistor materials may include carbon paste, plated nickel/chrome, or the like. Capacitors 261 may be formed between routing layers 260. The capacitors 261 may comprise a first plate and a second plate that are separated from each other by a high-k dielectric material.

In an embodiment, the second routing layers 260 may be used to communicatively couple a first die 225 to a second die 225. The dies 225 may be coupled to the second routing layers 260 through interconnects 222. For example, any first level interconnect (FLI) architecture (e.g., solder, copper bumps, etc.) may be used to couple the dies 225 to the second routing layers 260. The dies 225 may be embedded in a mold layer 223 with or without underfill around the interconnects 222.

Referring now to FIGS. 2B and 2C, plan view illustrations of a portion of the second routing layers 260 (FIG. 2B) and a portion of the first routing layers 240 are shown, in accordance with an embodiment. In FIG. 2B, the conductive traces 263 are provided between pads 265. In FIG. 2C, the conductive traces 243 are provided between pads 245. As shown, the width W₁ of the traces 263 is smaller than the width W₂ of the traces 243. For example, the width W₁ of the traces 263 may be approximately 5 μm or smaller, and the width W₂ of the traces 243 may be approximately 5 μm or larger. Similarly, the spacing S₁ between traces 263 is smaller than the spacing S₂ between the traces 243. For example, the spacing S₁ may be approximately 5 μm or smaller, and the spacing S₂ may be approximately 5 μm or larger. Additionally, the pads 265 may be provided at a smaller pitch than the pads 245. For example, the pads 265 may have a pitch that is approximately 25 μm or less in some embodiments. The thicknesses of the conductive features may also be different between the first routing layer 240 and the second routing layer 260. For example, pads 245 and traces 243 may have a thickness that is up to approximately 15 μm or thicker, and the pads 265 and traces 263 may have a thickness that is up to approximately 10 μm.

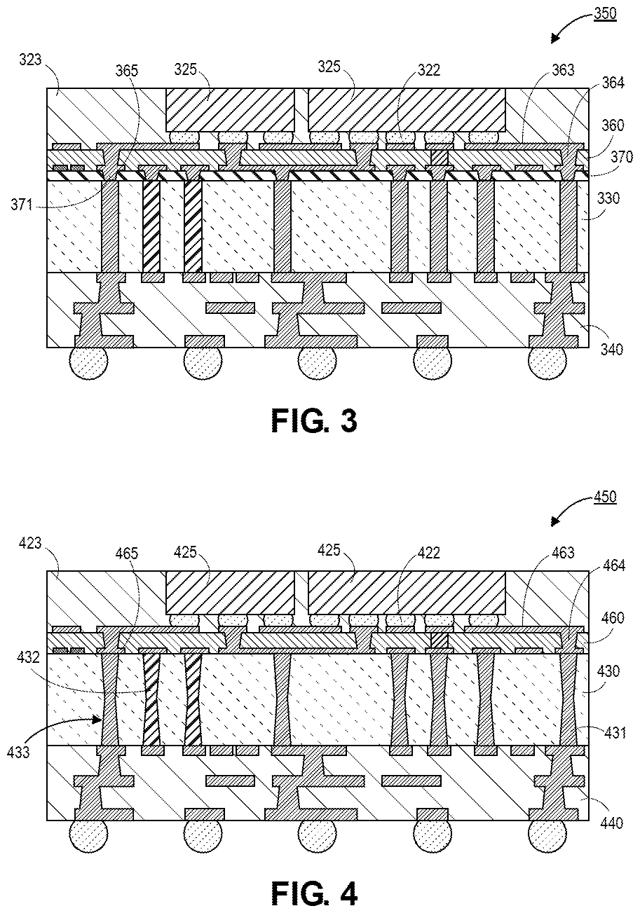

Referring now to FIG. 3, a cross-sectional illustration of an electronic package 350 is shown, in accordance with an additional embodiment. In an embodiment, the electronic package 350 may comprise a core 330, such as a glass core. First routing layers 340 may be provided below the core 330. In an embodiment, second routing layers 360 may be provided over the core 330. The second routing layers 360 may comprise traces 363, vias 364, and pads 365. The conductive routing may communicatively couple dies 325 together. The dies 325 may be coupled to the second routing layers 360 by interconnects 322, such as any FLI architecture. A mold layer 323 may be provided around the dies 325.

In an embodiment, a buffer layer 370 may be provided between the core 330 and the second buildup layers 360. The buffer layer 370 may be an electrically insulating material. In some embodiments, the buffer layer 370 may be a material that is different than the material of the second buildup layers 360. Though, in other embodiments, the buffer layer 370 may comprise the same material as the second buildup layers 360. The buffer layer 370 may be a material, such as a one comprising silicon and oxygen, silicon and nitrogen, a polymer, or any other suitable material. In an embodiment, the buffer layer 370 may comprise vias 371. The vias 371 provide electrical coupling between the conductive features of the second routing layers 360 to the conductive features of the core 330. In yet another embodiment, the buffer layer 370 may be provided between the first routing layers 340 and the core 330. In such an embodiment, the second routing layers 360 may be directly over the core 330. Embodiments may also include buffer layers 370 over the core 330 (i.e., between the core 330 and the second routing layers 360) and below the core 330 (i.e., between the core 330 and the first routing layers 340).

Referring now to FIG. 4, a cross-sectional illustration of an electronic package 450 is shown, in accordance with an additional embodiment. In an embodiment, the electronic package 450 may comprise a core 430, such as a glass core. First routing layers 440 may be provided below the core 430. In an embodiment, second routing layers 460 may be provided over the core 430. The second routing layers 460 may comprise traces 463, vias 464, and pads 465. The conductive routing may communicatively couple dies 425 together. The dies 425 may be coupled to the second routing layers 460 by interconnects 422, such as any FLI architecture. A mold layer 423 may be provided around the dies 425.

In an embodiment, the core 430 may comprise vias 431 and inductors 432. The vias 431 and inductors 432 may have sidewalls 433 that are non-vertical. Some patterning processes used to form the openings for the vias 431 and inductors 432 may result in tapered sidewalls 433. For example, a laser assisted patterning process may result in tapered sidewalls 433. In the particular embodiment shown in FIG. 4, the sidewalls 433 have a dual tapered shape. That is, the sidewalls 433 may result in vias 431 and inductors 432 that have an hourglass shaped cross-section. As used herein, an “hourglass shape” may refer to a shape that has a first end, a middle, and a second end, and the first end and the second end are wider than the middle.

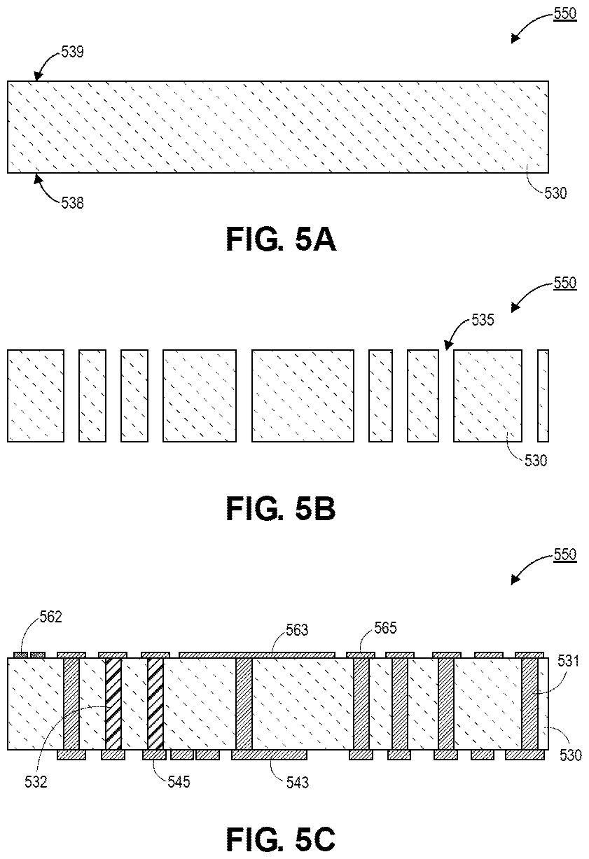

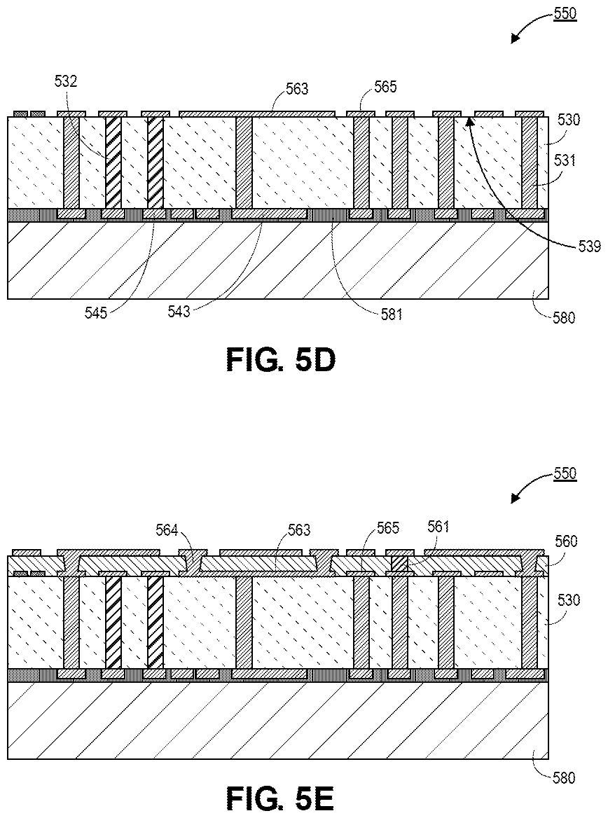

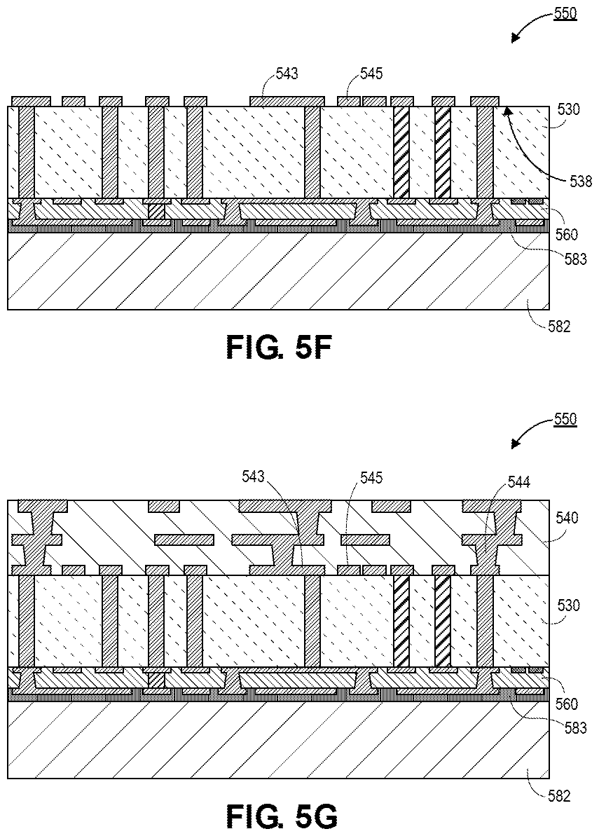

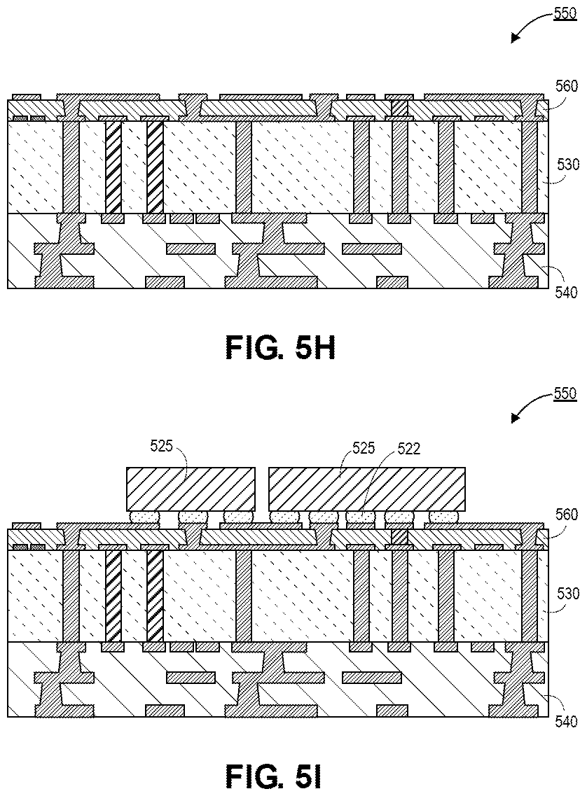

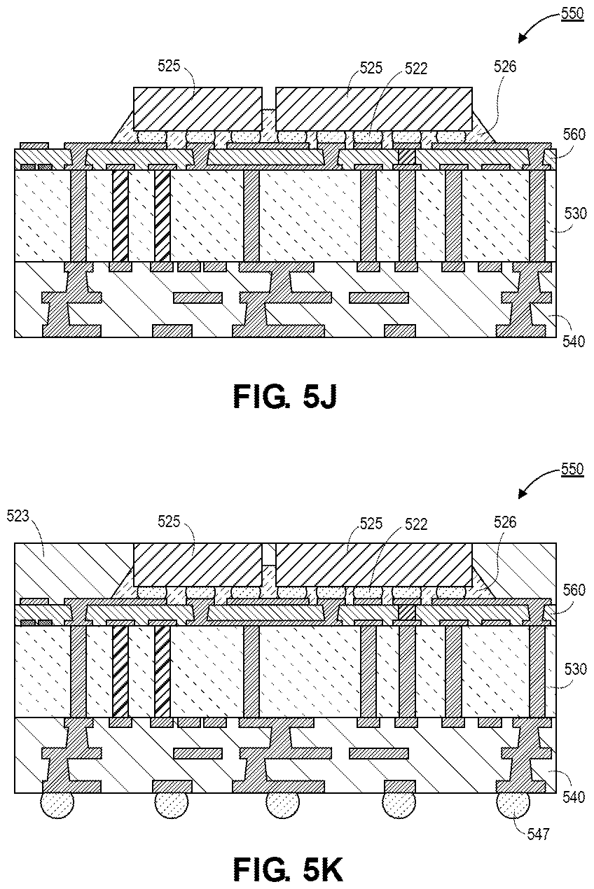

Referring now to FIGS. 5A-5K, a series of cross-sectional illustrations depicting a process for forming an electronic package 550 is shown, in accordance with an embodiment. In the illustrated embodiment, the electronic package 550 is similar to the electronic package 250 described in greater detail above. Though, it is to be appreciated that any of the electronic packages described herein may be formed with processes similar to those described in detail herein.

In the images shown in FIGS. 5A-5K, a single iteration of the electronic package 550 is shown. However, it is to be appreciated that processing may be implemented at a wafer level, a panel level, a quarter panel level, etc. That is, multiple electronic packages 550 may be fabricated substantially in parallel. Dicing operations may be implemented between certain processing operations in order reduce the structure to strips or a unit level.

Referring now to FIG. 5A, a cross-sectional illustration of an electronic package 550 at a stage of manufacture is shown, in accordance with an embodiment. In an embodiment, the electronic package 550 may comprise a core 530. The core 530 may include a first surface 538 and a second surface 539 opposite from the first surface 538. The core 530 may comprise a layer of glass. That is, the core 530 may comprise substantially all glass. The glass formulation of the core 530 may be compatible with laser assisted patterning processes. In an embodiment, the core 530 may have a thickness that is between approximately 50 μm and approximately 500 μm. Though, thinner or thicker cores 530 may be used in some embodiments.

Referring now to FIG. 5B, a cross-sectional illustration of the electronic package 550 after via openings 535 are formed through the core 530 is shown, in accordance with an embodiment. In an embodiment, the via openings 535 may be formed with a laser assisted patterning process. For example, a laser may be used to expose portions of the core 530. The exposed portions may undergo a change to a microstructure or phase of the glass. The change in structure may allow for the exposed regions to be etched preferentially to the unexposed regions. The etching process may be a wet or dry etching process. While a laser assisted etching process is described, it is to be appreciated that other patterning processes may also be used in order to form the openings 535.

In an embodiment, a diameter of the openings 535 may be approximately 100 μm or less, or approximately 50 μm or less, or approximately 20 μm or less. Larger diameters may also be used in some embodiments. In the illustrated embodiment, the via openings 535 are shown as having substantially vertical sidewalls. Though, it is to be appreciated that tapered sidewalls (e.g., hourglass shaped) may be provided in some embodiments.

Referring now to FIG. 5C, a cross-sectional illustration of the electronic package 550 after a plating process is shown, in accordance with an embodiment. In an embodiment, the plating process may be an electrolytic plating process in some embodiments. Residual portions of the seed layer used for plating the conductive features may be remove to expose portions of the core 530. The plating process may be used in order to form the vias 531. Inductors 532 may be formed substantially in parallel with the formation of the vias 531. The inductors 532 may be coaxial inductor structures with a magnetic shell around a conductive core. In an embodiment, the vias 531 and inductors 532 may be fully plated, or there may be an insulating core surrounded by the conductive material.

In an embodiment, the plating process may also result in the formation of traces 563 and pads 565 on one side of the core 530 and traces 543 and pads 545 on the other side of the core 530. Integrated passives such as a resistor 562 may also be formed with the plating process. As described in greater detail above, the traces 543 may have a larger line width (L/W) dimension than the traces 563.

Referring now to FIG. 5D, a cross-sectional illustration of the electronic package 550 after the core 530 is mounted to a carrier 580 is shown, in accordance with an embodiment. The core 530 may be mounted so that the second surface 539 of the core 530 is exposed. The core 530 may be attached to the carrier 580 by an adhesive 581. In an embodiment, the carrier 580 may be a dimensionally stable and rigid material. For example, the carrier 580 may be a glass carrier, a ceramic carrier, a silicon carrier, or the like.

Referring now to FIG. 5E, a cross-sectional illustration of the electronic package 550 after the fabrication of second routing layers 560 is shown, in accordance with an embodiment. In an embodiment, the second routing layers 560 may comprise silicon and oxygen, silicon and nitrogen, or a polymer. The conductive routing fabricated within the second routing layers 560 may include pads 565, traces 563, and vias 564. Additionally, passive components such as a capacitor 561 may be formed during the fabrications of the second routing layers 560. In the illustrated embodiment, two routing layers 560 are shown as one example. Other embodiments may include a single routing layer 560, four routing layers 560, or any other number of routing layers 560.

In an embodiment, one or more of the flatness, the rigidity, and the dimensional stability of the core 550 allow for the fabrication of high density conductive features. For example, traces 563 may have L/S dimensions that are approximately 5 μm/5 μm or less, or approximately 1 μm/1 μm or less. Pads 565 for connecting to overlying dies (not yet attached) may have a pitch of approximately 25 μm or less.

Referring now to FIG. 5F, a cross-sectional illustration of the electronic package 550 after the core 530 is flipped and mounted to a second carrier 582 is shown, in accordance with an embodiment. In an embodiment, FIG. 5F is shown after the first carrier 580 is removed and the adhesive 581 is cleaned from the first surface 538 of the core 530. The second carrier 582 may be coupled to the second routing layers 560 by an adhesive 583 or the like. The second carrier 582 may be a dimensionally stable and rigid material. For example, the second carrier 582 may be a glass carrier, a ceramic carrier, a silicon carrier, or the like.

Referring now to FIG. 5G, a cross-sectional illustration of the electronic package 550 after first routing layers 540 are provided over the core 530 is shown, in accordance with an embodiment. In an embodiment, the first routing layers 540 may comprise buildup film or other organic dielectric materials. In an embodiment, the layers are laminated over each other. Additionally, conductive routing (e.g., pads 545, traces 543, and vias 544) may be provided through the first routing layers 540. The conductive features may be formed with standard processes, such as a semi-additive process (SAP). In the illustrated embodiment, three routing layers are shown. Though, it is to be appreciated that any number of first routing layers 540 may be used.

In an embodiment, the traces 543 may have an L/S dimension that is larger than the L/S dimension of the traces 563 in the second routing layers 560. For example, the traces 543 may have L/S dimensions that are approximately 5 μm/5 μm or greater, or approximately 15 μm/15 μm or greater. The thickness of traces 543 may also be greater than the thickness of traces 563.

Referring now to FIG. 5H, a cross-sectional illustration of the electronic package 550 after the second carrier 582 is removed is shown, in accordance with an embodiment. The second carrier 582 may be removed with any suitable process. In some embodiments, the adhesive 583 may also be cleaned from the second routing layers 560.

Referring now to FIG. 5I, a cross-sectional illustration of the electronic package 550 after dies 525 are attached is shown, in accordance with an embodiment. In an embodiment, the dies 525 may be connected to the second routing layers 560 through any suitable FLI architecture. For example, interconnects 522 may be solder balls or the like. The conductive features in the second routing layers 560 may be used to communicatively couple the pair of dies 525 together.

In an embodiment, the dies 525 may be any type of die. The dies 525 may be compute dies. For example, the dies 525 may comprise a central processing unit (CPU), a graphics processing unit (GPU), an XPU, a system on a chip (SoC), a communications die, a memory, or the like. In an embodiment, the dies 525 may be similar to each other. In other embodiments, the dies 525 may be different types.

Referring now to FIG. 5J, a cross-sectional illustration of the electronic package 550 after an underfill 526 is applied is shown, in accordance with an embodiment. In an embodiment, the underfill 526 may be a capillary underfill (CUF) material. The underfill 526 may surround the interconnects 522 below the dies 525. Any suitable underfill 526 material may be used around the interconnects 522.

Referring now to FIG. 5K, a cross-sectional illustration of the electronic package 550 after a mold layer 523 is applied is shown, in accordance with an embodiment. In an embodiment, the mold layer 523 may be any suitable molding material, such as an epoxy or the like. The mold layer 523 may embed the dies 525. In some embodiments, the underfill 526 may be omitted. In such embodiments, the mold layer 523 may also surround the interconnects 522.

In addition to the forming the mold layer 523, embodiments may include forming interconnects 547. The interconnects 547 may be any SLI architecture. In an embodiment, interconnects 547 may be provided at a bottom of the first routing layers 540. For example, the interconnects 547 are shown as solder balls. Though, in other embodiments, the interconnects 547 may be a socketing architecture, or the like.

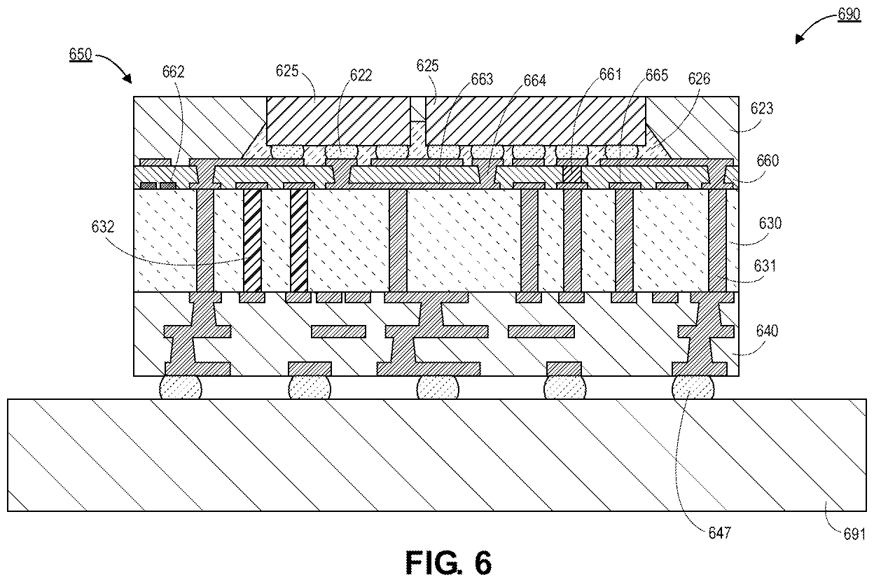

Referring now to FIG. 6, a cross-sectional illustration of an electronic system 690 is shown, in accordance with an embodiment. In an embodiment, the electronic system 690 comprises a board 691, such as a printed circuit board (PCB). The board 691 may be coupled to an electronic package 650 by interconnects 647, such as solder balls, sockets, or the like.

In an embodiment, the electronic package 650 may be similar to any of the electronic packages described in greater detail herein. In a particular embodiment, the electronic package 650 comprises a core 630, such as a glass core 630. Vias 631 and integrated inductors 632 may be provided through the core 630. In an embodiment, first routing layers 640 may be provided below the core 630. Additionally, second routing layers 660 may be provided over the core 630.

In an embodiment, the second routing layers 660 may comprise pads 665, traces 663, and vias 664. The traces 663 may have L/S dimensions that are approximately 5 μm/5 μm or smaller, or approximately 1 μm/1 μm or smaller. The second routing layers 660 may also comprise passive devices, such as resistors 662 and capacitors 661.

In an embodiment, dies 625 may be coupled to the second routing layers 660 through interconnects 622. The dies 625 may be communicatively coupled to each other through the conductive routing in the second routing layers 660. The interconnects 622 may be surrounded by an underfill 626, such as a CUF. In an embodiment, a mold layer 623 is provided around the dies 625.

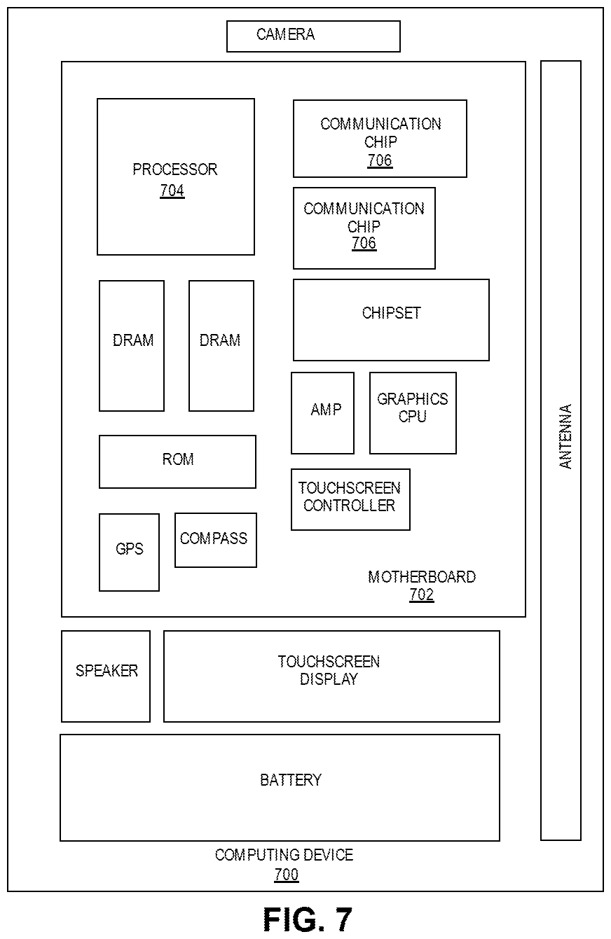

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package with a glass core with a first routing layer on one side and a second routing layer on the other side in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of electronic package with a glass core with a first routing layer on one side and a second routing layer on the other side, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.
Example 1: a package substrate, comprising: a core with a first surface and a second surface, wherein the core comprises a glass layer, wherein the glass layer comprises approximately 70% silicon or more; a first routing layer over the first surface of the core, wherein the first routing layer comprises traces with a first width; and a second routing layer over the second surface of the core, wherein the second routing layer comprises traces with a second width that is smaller than the first width.
Example 2: the package substrate of Example 1, further comprising vias through the core.
Example 3: the package substrate of Example 2, wherein the vias have an hourglass shaped cross-section.
Example 4: the package substrate of Examples 1-3, wherein the second width is approximately 5 μm or less.
Example 5: the package substrate of Example 4, wherein the second width is approximately 1 μm or less.
Example 6: the package substrate of Examples 1-5, wherein a thickness of the second routing layer is approximately 10 μm or less.
Example 7: the package substrate of Examples 1-6, further comprising: one or more passive devices embedded in the second routing layer.
Example 8: the package substrate of Example 7, wherein the one or more passive devices comprises a resistor and/or a capacitor.
Example 9: the package substrate of Examples 1-8, further comprising: an inductor embedded in the core.
Example 10: the package substrate of Examples 1-10, further comprising: a layer between the core and the second routing layer, wherein the layer is an insulating material.
Example 11: an electronic package, comprising: a package substrate with a glass core, first routing layers under the glass core, and second routing layers over the glass core; a first die coupled to the package substrate; and a second die coupled to the package substrate, wherein the second routing layers communicatively couple the first die to the second die.
Example 12: the electronic package of Example 11, wherein the second routing layers comprise traces with a width that is approximately 1 μm or less.
Example 13: the electronic package of Example 11 or Example 12, wherein the core has a thickness that is less than approximately 1,000 μm.
Example 14: the electronic package of Examples 11-13, wherein vias pass through the core to electrically couple the first routing layers to the second routing layers.
Example 15: the electronic package of Examples 11-14, wherein the second routing layers comprise one or more redistribution layers.
Example 16: the electronic package of Examples 11-15, further comprising an inductor, a resistor, and/or a capacitor embedded in one or both of the core and the second routing layers.
Example 17: the electronic package of Examples 11-16, further comprising: a layer between the glass core and the second routing layers, wherein the layer comprises an insulating material, and wherein the glass core comprises approximately 70% silicon or more.
Example 18: an electronic system, comprising: a board; a package substrate coupled to the board, wherein the package substrate comprises: a core, wherein the core comprises a glass layer; one or more buildup layers under the core, wherein the one or more buildup layers comprise first traces with a first trace width that is approximately 5 μm or greater; and one or more redistribution layers over the core, wherein the one or more redistribution layers comprise second traces with a second trace width that is approximately 5 μm or less; a first die coupled to the package substrate; and a second die coupled to the package substrate, wherein the first die is communicatively coupled to the second die by second traces.
Example 19: the electronic system of Example 18, further comprising: a resistor, a capacitor, and/or an inductor embedded in the package substrate.
Example 20: the electronic system of Example 18 or Example 19, wherein the electronic system is part of a personal computer, a server, a mobile device, a tablet, or an automobile.

What is claimed is:

1. A package substrate, comprising:
a core with a first surface and a second surface, wherein the core comprises a glass layer, wherein the glass layer comprises approximately 70% silicon or more;
a first routing layer over the first surface of the core, wherein the first routing layer comprises traces with a first width; and
a second routing layer over the second surface of the core, wherein the second routing layer comprises traces with a second width that is smaller than the first width.

2. The package substrate of claim 1, further comprising vias through the core.

3. The package substrate of claim 2, wherein the vias have an hourglass shaped cross-section.

4. The package substrate of claim 1, wherein the second width is approximately 5 μm or less.

5. The package substrate of claim 4, wherein the second width is approximately 1 μm or less.

6. The package substrate of claim 1, wherein a thickness of the second routing layer is approximately 10 μm or less.

7. The package substrate of claim 1, further comprising:
one or more passive devices embedded in the second routing layer.

8. The package substrate of claim 7, wherein the one or more passive devices comprises a resistor and/or a capacitor.

9. The package substrate of claim 1, further comprising:
an inductor embedded in the core.

10. The package substrate of claim 1, further comprising:
a layer between the core and the second routing layer, wherein the layer is an insulating material.

11. An electronic package, comprising:
a package substrate with a glass core, first routing layers under the glass core, and second routing layers over the glass core;
a first die coupled to the package substrate; and
a second die coupled to the package substrate, wherein the second routing layers communicatively couple the first die to the second die.

12. The electronic package of claim 11, wherein the second routing layers comprise traces with a width that is approximately 1 μm or less.

13. The electronic package of claim 11, wherein the core has a thickness that is less than approximately 1,000 μm.

14. The electronic package of claim 11, wherein vias pass through the core to electrically couple the first routing layers to the second routing layers.

15. The electronic package of claim 11, wherein the second routing layers comprise one or more redistribution layers.

16. The electronic package of claim 11, further comprising an inductor, a resistor, and/or a capacitor embedded in one or both of the core and the second routing layers.

17. The electronic package of claim 11, further comprising:
a layer between the glass core and the second routing layers, wherein the layer comprises an insulating material, and wherein the glass core comprises approximately 70% silicon or more.

18. An electronic system, comprising:
a board;
a package substrate coupled to the board, wherein the package substrate comprises:
a core, wherein the core comprises a glass layer;
one or more buildup layers under the core, wherein the one or more buildup layers comprise first traces with a first trace width that is approximately 5 μm or greater; and
one or more redistribution layers over the core, wherein the one or more redistribution layers comprise second traces with a second trace width that is approximately 5 μm or less;
a first die coupled to the package substrate; and
a second die coupled to the package substrate, wherein the first die is communicatively coupled to the second die by second traces.

19. The electronic system of claim 18, further comprising:
a resistor, a capacitor, and/or an inductor embedded in the package substrate.

20. The electronic system of claim 18, wherein the electronic system is part of a personal computer, a server, a mobile device, a tablet, or an automobile.
